(19) United States
(12) Patent Application Publication
(10) Pub. No.: US 2018/0284977 A1
(43) Pub. Date: Oct. 4, 2018

(54) ELECTRONIC DEVICES, METHODS FOR CONTROLLING USER INTERFACE AND METHODS FOR SENSING TOUCH OBJECT

(71) Applicant: Acer Incorporated, New Taipei City (TW)

(72) Inventors: Chueh-Pin KO, New Taipei City (TW); Chih-Chiang CHEN, New Taipei City (TW)

(21) Appl. No.: 15/913,777

(22) Filed: Mar. 6, 2018

(30) Foreign Application Priority Data
Mar. 30, 2017 (TW) 106110757
Nov. 6, 2017 (TW) 106138297

(51) Int. Cl. G06F 3/0484; G06F 3/041

(52) U.S. Cl. CPC G06F 3/04847; G01R 19/0007; G06F 3/0414

(57) ABSTRACT

An electronic device includes a storage device, a touch sensing unit, and a processor. The storage device stores predetermined contact point information corresponding to a control object. The touch sensing unit detects a touch event corresponding to at least one touch object and outputs a touch signal. The processor receives the touch signal and determines whether the contact point information of the touch signal conforms to the predetermined contact point information corresponding to the control object. When the processor determines that the contact point information of the touch signal conforms to the predetermined contact point information, the processor enables a function corresponding to the control object.

### CROSS REFERENCE TO RELATED APPLICATIONS

This Application claims priority of Taiwan Patent Application No. 106110757, filed on Mar. 30, 2017, and Taiwan Patent Application No. 106138297, filed on Nov. 6, 2017, the entirety of which is incorporated by reference herein.

### BACKGROUND OF THE INVENTION

### Field of the Invention

The present invention relates to an electronic device, and more particularly to an electronic device and a method for controlling a user interface for enabling a function corresponding to a control object when contact point information of a touch object conforms to a predetermined pattern.

### Description of the Related Art

At present, input devices transmit data in a wired or wireless manner. For example, one wired technique includes connecting the input device to the master device via a USB transmission line, and a wireless technique may be to connect the input device to the master device via Bluetooth or WiFi. Because the input device connects to the master device in a wired or wireless way, an additional port or communication module is needed, which will increase the cost of the product. Therefore, how to connect the input device and the master device in a simple and low-cost way is a problem that needs to be solved immediately.

### BRIEF SUMMARY OF INVENTION

An embodiment of the present invention provides an electronic device, including a storage device, a touch sensing unit, and a processor. The storage device stores predetermined contact point information corresponding to a control object. The touch sensing unit detects a touch event corresponding to at least one touch object and outputs a touch signal. The processor receives the touch signal and determines whether the contact point information of the touch signal conforms to the predetermined contact point information corresponding to the control object. When the processor determines that the contact point information of the touch signal conforms to the predetermined contact point information, the processor enables a function corresponding to the control object.

Another embodiment of the present invention provides a method for controlling a user interface, adapted to an electronic device, wherein the steps include: detecting, via a touch sensing unit, a touch event corresponding to at least one touch object; outputting, via the touch sensing unit, a touch signal according to the touch event; receiving, via a processor, the touch signal from the touch sensing unit; and determining, via the processor, whether contact point information of the touch signal conforms to predetermined contact point information corresponding to a control object, wherein the predetermined contact point information is stored in a storage device. When the contact point information of the touch signal conforms to the predetermined contact point information, the processor enables a function corresponding to the control object.

Another embodiment of the present invention provides an electronic device, including a storage device, a touch-sensing unit, and a processor. The storage device stores predetermined contact point information corresponding to a control object, wherein the predetermined contact point information includes a first electrical signal corresponding to a first contact point and a second electrical signal corresponding to a second contact point. The touch-sensing unit detects a touch event corresponding to at least one touch object and outputs a touch signal. The processor receives the touch signal and determines whether the touch-sensing information corresponding to the touch signal conforms to the predetermined contact point information corresponding to the control object. When the processor determines that the touch-sensing information of the touch signal conforms to the predetermined contact point information, the processor enables the function that corresponds to the control object.

Another embodiment of the present invention provides a method for sensing a touch object, adapted to an electronic device, including: detecting, using a touch-sensing unit, a touch event corresponding to at least one touch object; outputting, using the touch-sensing unit, a touch signal according to the touch event; receiving, using a processor, the touch signal from the touch-sensing unit; and determining, using the processor, whether touch-sensing information corresponding to the touch signal conforms to predetermined contact point information corresponding to a control object; wherein the predetermined contact point information further comprises a first electrical signal corresponding to a first contact point and a second electrical signal corresponding to a second contact point, and the predetermined contact point information is stored in a storage device; and wherein the processor enables the function that corresponds to the control object when the touch-sensing information of the touch signal conforms to the predetermined contact point information.

### BRIEF DESCRIPTION OF DRAWINGS

The invention can be more fully understood by reading the subsequent detailed description and examples with references made to the accompanying drawings, wherein:

FIG. 1 is a block diagram of the electronic device in accordance with an embodiment of the present invention.

FIG. 2 is a side view of the control object in accordance with an embodiment of the present invention.

FIG. 3 is a schematic diagram of the predetermined contact point information corresponding to the control object in accordance with an embodiment of the present invention.

FIG. 4 is a schematic diagram of the predetermined contact point information corresponding to another control object in accordance with another embodiment of the present invention.

FIG. 5 is a flow chart of the method for controlling the user interface in accordance with an embodiment of the present invention.

FIG. 6 is a block diagram of an electronic device in accordance with an embodiment of the invention.

FIG. 7 is a block diagram of a control object in accordance with an embodiment of the present invention.

FIG. 8 is a side view of the control object in accordance with an embodiment of the present invention.

FIG. 9 is a schematic diagram of field patterns corresponding to contact points having different widths in accordance with an embodiment of the present invention.

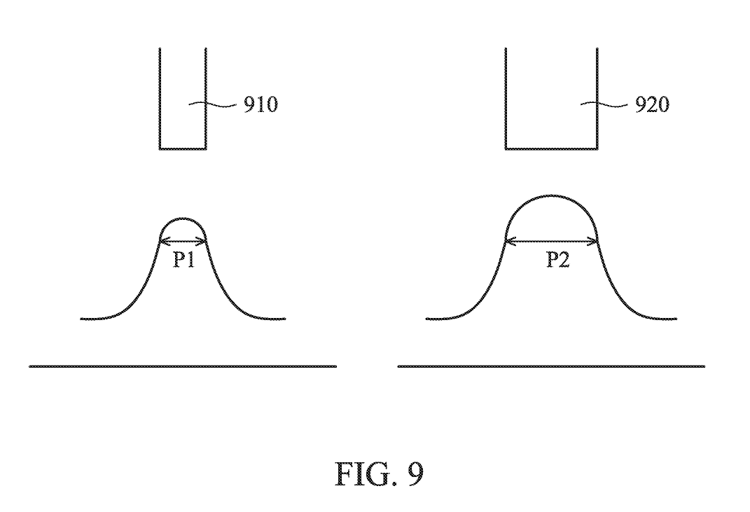

FIG. 10 is a schematic diagram of a rotatable control object in accordance with an embodiment of the present invention.

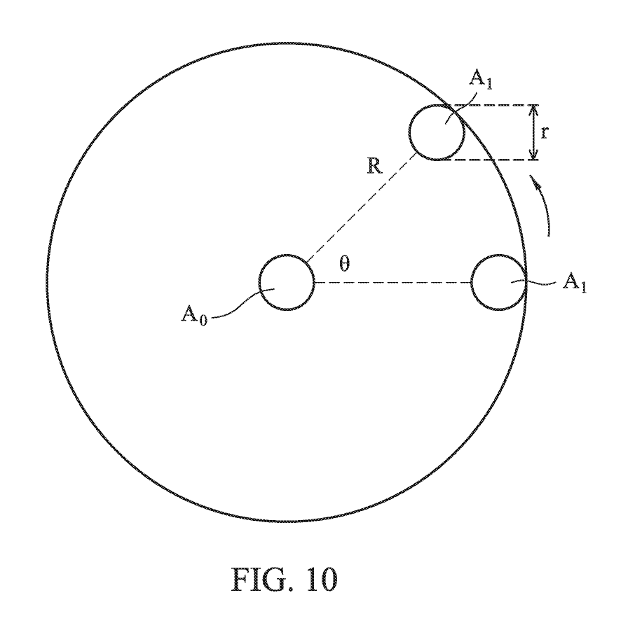

FIG. 11 is a flow chart of a method for sensing a touch object in accordance with an embodiment of the present invention.

### DETAILED DESCRIPTION OF INVENTION

Further areas to which the present electronic devices, methods for controlling a user interface and methods for sensing touch objects can be applied will become apparent from the detailed description provided herein. It should be understood that the detailed description and specific examples, while indicating exemplary embodiments of electronic devices and methods for controlling a user interface, are intended for the purposes of illustration only and are not intended to limit the scope of the invention.

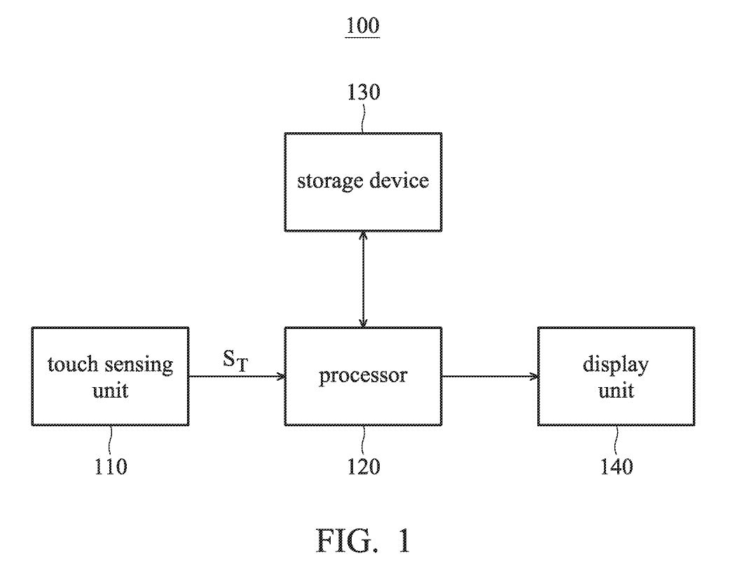

FIG. 1 is a block diagram of an electronic device 100 according to an embodiment of the present invention. As shown in FIG. 1, the electronic device 100 includes a touch sensing unit 110, a processor 120, a storage device 130, and a display unit 140. The touch sensing unit 110 is composed of a plurality of induction electrodes, and is configured to detect a touch event corresponding to at least one touch object based on a change of induction on the sensing electrode and to output a touch signal S_{T} corresponding to the touch event. The processor 120 can be a CPU, a microcontroller, or a System on Chip (SoC), etc., and is configured to perform a user interface, receive the touch signal S_{T} from the touch sensing unit 110 and determine whether the touch object conforms to the control object according to the contact point information containing in the received touch signal S_{T} for enabling the function corresponding to the control object. The contact point information includes the configuration of the touch points, the number of touch points and/or the induction corresponding to each contact point. The storage device 130 can be a flash drive, a hard disk, or any type of memory or the like, and is configured to store the contact point information corresponding to the control objects. In another embodiment, the storage device 130 can also be integrated with the processor 120 in the same chip for miniaturization. The display unit 140 displays a user interface, and displays an operation screen according to the operation corresponding to the touch event. The touch sensing unit 110 can be integrated with the display unit 140 as a touch screen.

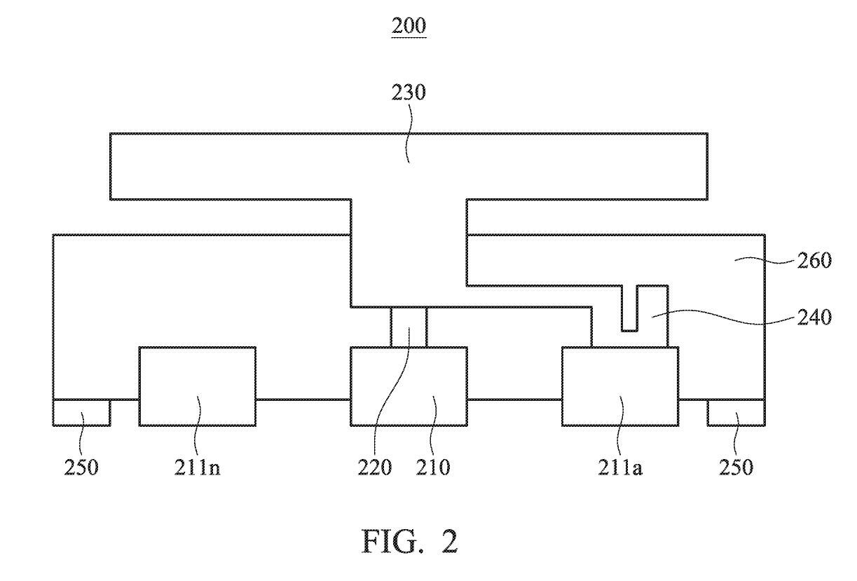

FIG. 2 is a side view of the control object in accordance with an embodiment of the present invention. The control object 200 can be an electroless element having a knob structure (e.g., an electroless knob), the contact point of the control object 200 touched with the touch sensing unit 110 is composed of a conductive element. When the control object comes into contact with the touch sensing unit 110 through the contact point, only the induction on the touch sensing unit 110 changes, and no signal is sent to the processor 12. As shown in FIG. 2, the control object 200 is composed of a center contact point 210, peripheral contact points 211a to 211n, a rotation shaft 220, a knob 230, a contact structure 240, a fixing member 250, and a case 260. The fixing member 250 can be a suction cup or a reusable adhesive material or the like. When the knob 230 is rotated, the contact structure 240 can also be rotated to contact the different contacts 211a to 211n. It should be noted that the control object 200 can also be affixed to the touch sensing unit 110 with a clip.

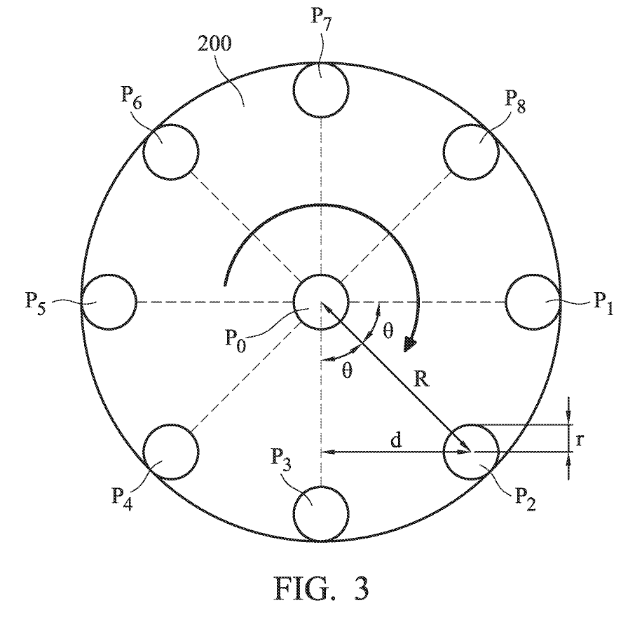

According to an embodiment of the present invention, when the touch sensing unit 110 detects a touch event corresponding to the touched object and outputs the corresponding touch signal S_{T}, the processor 120 determines the type of touch object it is according to the contact point information containing in the touch signal S_{T} to correctly output the corresponding function. For example, FIG. 3 is a schematic diagram of the predetermined contact point information corresponding to the control object 200 in accordance with an embodiment of the present invention. The contact point information of the control object 200 shown in FIG. 3 has been stored in the storage device 130 in advance. As shown in FIG. 3, the control object has nine contact points P₀ to P₈, the contact point P₀ is the center contact point, and the angle θ between each contact point P₁ to P₈ is 45°. The size of the angle θ is determined by the number of contact points around the center contact point, e.g., the greater the number of surrounding contact points, the more switchable segments of the control object there are, and the smaller the angle θ becomes. The lateral distance d between two contact points is determined by the radius r of the contact point and the sensor pitch, e.g., the narrower the width of the sensing electrode, the smaller the size of the control objects 200. In general, the channel space is from 4 to 6 mm, and the diameter of the contact point is from 6 to 9 mm. For example, when the sensor pitch is 5 mm, the diameter of the contact point is 9 mm, the number of switchable segments is 12 (e.g., θ is 30°), and the radius R of the control object is at least 28 mm.

When the processor 120 receives the touch signal S_{T}, it determines whether the touch object is the control object by: (1) determining whether the distribution of the contact points is the same as the distribution of the contact points of the control object according to the coordinates of each of the contact points of the touch object; (2) determining whether the number of contact points of the touch object is 9; (3) determining whether the induction of two of the contact points is greater than the others (because when the control object comes into contact with the touch sensing unit, the center contact point and one of the surrounding contact points are connected through the contact structure). When the contact point information of the touch signal S_{T} conforms to any of the conditions as described above, the processor 120 determines that the touch object is the control object and enables the function corresponding to the control object according to the current application. For example, when the current display screen of the display unit 140 is the main screen of the operating system, the function corresponding to the control object can be the brightness control of the display screen. However, when the processor 120 is executing the multimedia player program, the function corresponding to the control object can be the volume control. Furthermore, when the processor 120 is executing a drawing program or a notebook-related program, the function corresponding to the control object can be a change in the color or an adjustment of the thickness of a brush. In addition, when the processor 120 determines that the touch object leaves the touch sensing unit 110, the processor 120 disables the function corresponding to the control object.

It should be noted that when the processor 120 determines that the touch object is a control object, a prompt window can be displayed on the user interface to tell the user that the function corresponding to the control object can be started.

In addition, after the processor 120 determines that the touch object is a control object, the processor 120 can output a control signal corresponding to the function of the control object according to the coordinate change and/or the rotation angle of the contact point having a large amount of induction. For example, when the processor 120 determines that two of the contact points having the maximum induction are changed from the contact points P0, P1 to the contact points P0, P2 while the function corresponding to the control object is the volume control, the processor 120 determines that the control object switches one segment clockwise, and the processor 120 turns the volume up one level. Alternatively, when the processor 120 determines that the knob is rotated 90° clockwise while the control object is a knob having eight segments, the processor 120 determines that the control object switches two segments, and the processor 120 turns the volume up two levels. It should be noted that, according to the contents shown in FIG. 3, the control object is designed as a circulation-type design in which the knob can be rotated in one direction infinitely.

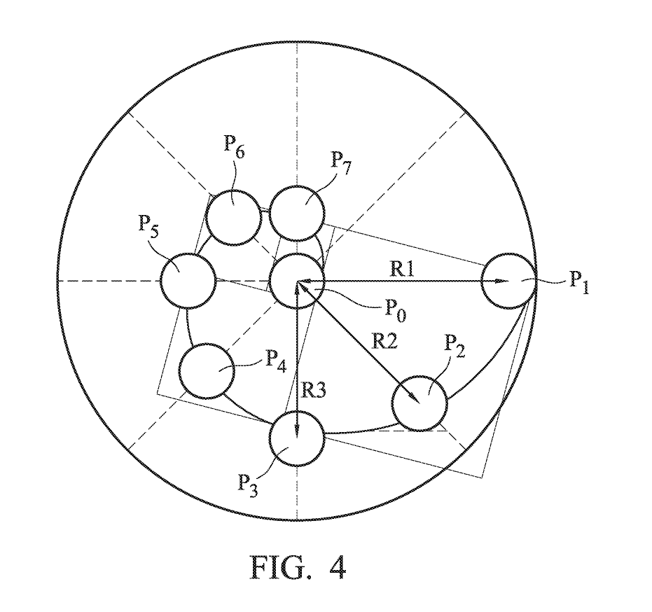

FIG. 4 is a diagram showing the predetermined contact point information corresponding to another control object according to another embodiment of the present invention. As shown in FIG. 4, the control object is designed as a non-cyclic design in which the contact structure 240 of the knob can only rotate clockwise to the position of the contact point P8.

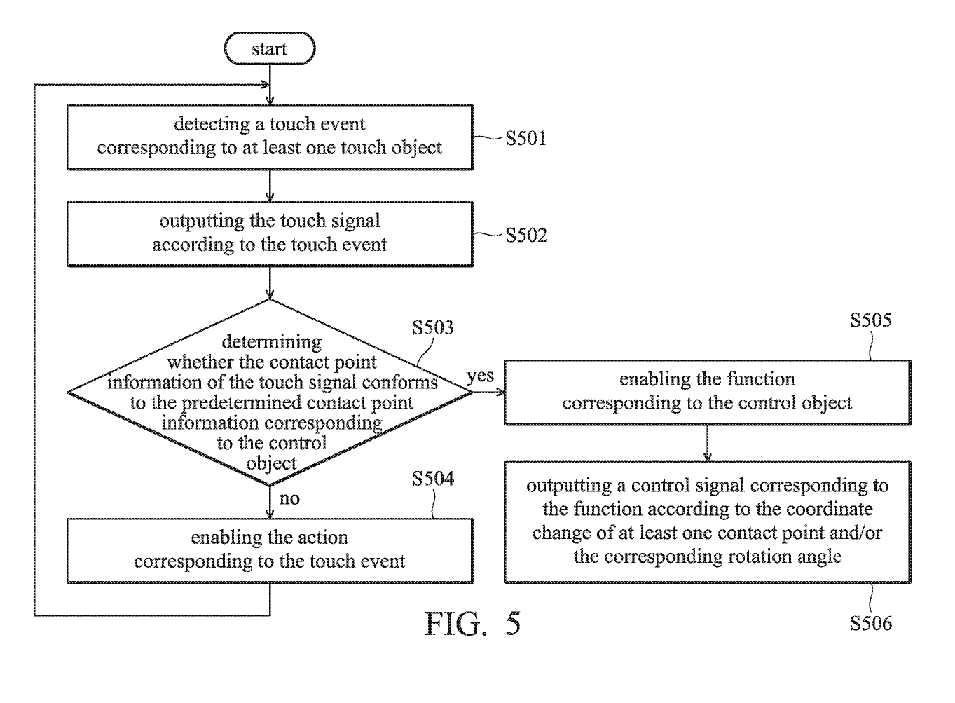

FIG. 5 is a flow chart of the method for controlling the user interface in accordance with an embodiment of the present invention. In step S501, the touch sensing unit 110 detects a touch event corresponding to at least one touch object. In step S502, the touch sensing unit 110 outputs the touch signal S_{T} according to the touch event. In step S503, the processor 120 receives the touch signal S_{T} and determines whether the contact point information of the touch signal S_{T} conforms to the predetermined contact point information corresponding to the control object. If not, the method proceeds to step S504, the processor 120 enables the action corresponding to the touch event, and returns to step S501. If so, the method proceeds to step S505, the processor 120 enables the function corresponding to the control object. In step S506, the processor 120 outputs a control signal corresponding to the function according to the coordinate change of at least one contact point and/or the corresponding rotation angle.

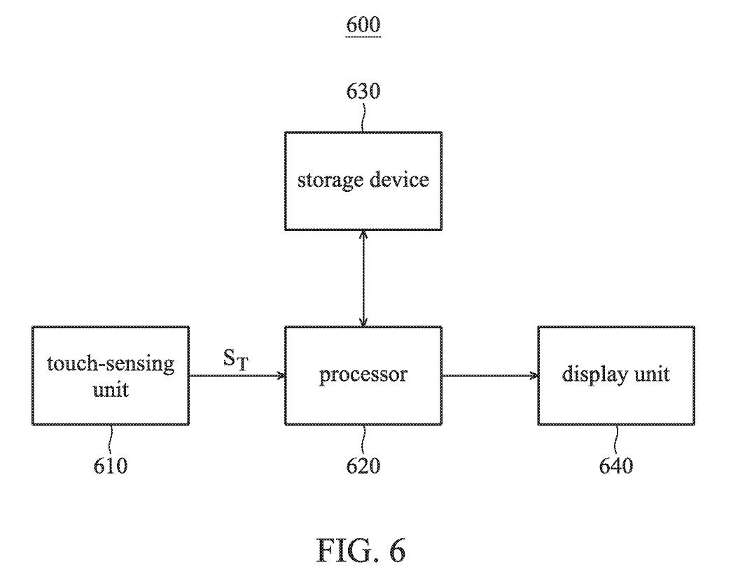

FIG. 6 is a block diagram of an electronic device 600 according to an embodiment of the present invention. The electronic device 600 can be a device having a sensing LCD screen or a touch screen. The electronic device 600 at least includes a touch-sensing unit 610, a processor 620, a storage device 630, and a display unit 640. The touch-sensing unit 610 is composed of a plurality of induction electrodes, and is configured to detect a touch event corresponding to at least one touch object based on a change of induction on the sensing electrode and output a touch signal S_{T} corresponding to the touch event. The processor 620 can be a CPU, a microcontroller (MCU), or a System on Chip (SoC), etc., and is configured to perform a plurality of instructions and a user interface, and can display operating results through the user interface based on the touch signal S_{T} received from the touch-sensing unit 610. The storage device 630 can be a flash drive, a hard disk, or any type of memory, and is configured to store the contact point information corresponding to at least one control object. In another embodiment, the storage device 630 can also be integrated with the processor 620 in the same chip for miniaturization. The display unit 640 can be integrated with the touch-sensing unit 610 as a touch screen for displaying the user interface and the operating effects corresponding to the touch event.

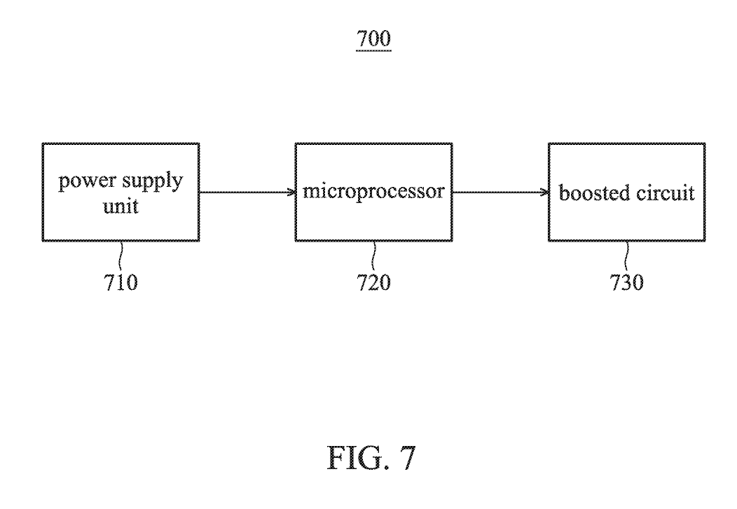

FIG. 7 is a block diagram of a control object in accordance with an embodiment of the present invention. The control object 700 is an object having a knob structure and is composed of a power supply unit 710, a microprocessor 720 and a boosted circuit 730. The power supply unit 710 can be an electric power-supply circuit with a capacitor or a battery, for supplying power to the microprocessor 720 and the boosted circuit 730 through a wired connection. Alternatively, the power supply unit 710 can also be a sensing circuit composed of components such as an induction coil, a variable capacitor and an inductor. When the touch panel of the electronic device 600 is an electromagnetic touch panel or a part of the touch panel is an electromagnetic touch panel, the control object 700 can transmit power by electromagnetic induction (a wireless method) through the sensing circuit. The microprocessor 720 outputs an active signal via the contact points through the boosted circuit 730. The active signal generated by the boosted circuit 730 can be a specific voltage or have a specific frequency.

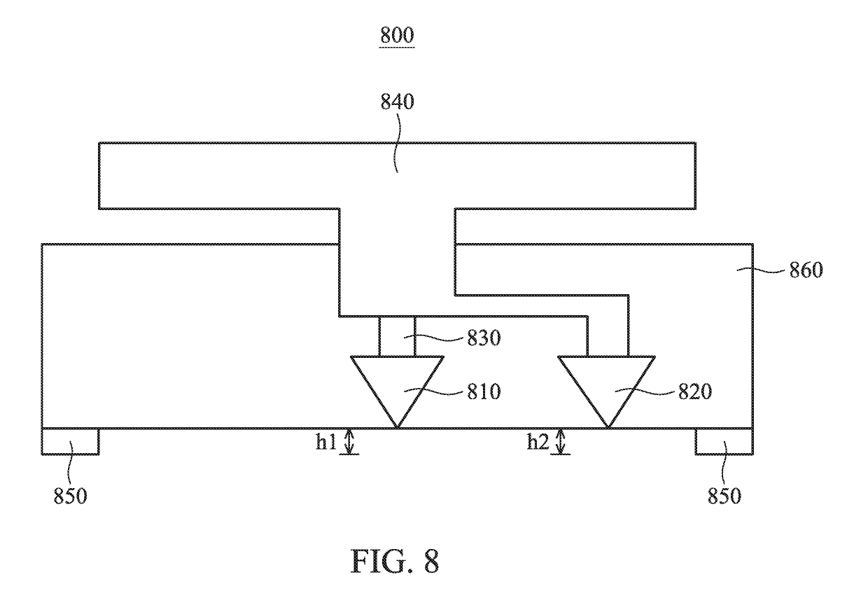

FIG. 8 is a side view of a control object in accordance with an embodiment of the present invention. As shown in FIG. 8, the control object 800 includes at least a first contact point 810, a second contact point 820, a rotation shaft 830, a knob 840, a plurality of fixing members 850 and a case 860. The first contact point 810 and the second contact point 820 are made of a conductive material so that the boosted circuit 730 can output the active signal through the first contact point 810 and the second contact point 820. In order to maintain electrical stability and extend the service life of the control object 800, the first contact point 810 and the second contact point 820 may also be covered by a non-conductive material. In addition, since the control object 800 actively outputs the electrical signal through the first contact point 810 and the second contact point 820, the first contact point 810 and the second contact point 820 may not be directly contacted with the touch panel (i.e., the first contact point 810 and the second contact point 820 are respectively separated from the touch panel by a distance h1, h2). The fixing member 850 can be a suction cup, a reusable adhesive, for example, so that the control object 800 can be affixed to the touch panel through the fixing member 850. In addition, the control object 800 may also be affixed to the electronic device 600 using a clip.

According to an embodiment of the present invention, when the touch-sensing unit 610 detects the touch event corresponding to the touch object and outputs the corresponding touch signal S_{T}, the processor 620 may determines whether the touch object is the control object 700 according to touch-sensing information contained in the touch signal S_{T} to perform the corresponding operation correctly. The touch-sensing information may include a frequency output from the contact point output, a field pattern generated by the contact point, or a voltage strength sensed by the touch-sensing unit 610, for example. The field pattern refers to the shape of the two-dimensional electric field distribution generated by the voltage output by the contact point on the touch screen. When the touch information contained in the touch signal S_{T} matches any one of the frequency, the field pattern or the voltage strength corresponding to the control object 700 stored in the storage device 630, the processor 620 determines that the touch object is the control object 700 and enables the corresponding function.

TABLE 1

| | first contact point | second contact point |
|---|---|---|
| frequency | 80 KHz, 40 V | 110 KHz, 40 V |
| field pattern | circle, 40 V | rectangle, 40 V |
| voltage strength | 2 mm, 40 V | 5 mm, 40 V |
| | 2 mm, 40 V | 2 mm, 40 V |

Table 1 shows the contact information that can be used to determine whether the touch object is the control object in accordance with some embodiments of the present invention. The touch information corresponding to the control object has been stored in the storage device 630 in advance as a basis for the processor 620 to make the determination. When the processor 620 determines that the touch object has two contact points and the touch-sensing information received by the touch-sensing unit 610 meets one of the predetermined conditions shown in Table 1, the processor 620 determines that the touch object is the control object.

In addition, in order to allow the processor 620 to further identify the difference between the first contact point 810 and the second contact point 820, the control object may output different frequencies through the microprocessor 720, or the first contact point 810 and the second contact point 820 can be designed to have different shapes or provide different voltage intensities to the touch screen to identify the first contact points 810 and the second contact points 820. For example, as shown in Table 1, the first contact point 810 and the second contact point 820 respectively output frequencies of 80 KHz and 110 KHz for the processor 620 to identify the first contact point 810 and the second contact point 820.

Alternatively, according to another embodiment of the present invention, in addition to output different frequencies through the microprocessor 720, the processor 620 may identify the first contact point 810 and the second contact point 820 based on the shapes of the first contact point 810 and the second contact point 820 or the voltage intensity provided to the touch screen. For example, when the control object is designed, the outer shapes of the first contact points 810 and the second contact points 820 are respectively defined as circle and rectangle, so as to respectively form a circular field and a rectangular field on the touch-sensing unit 610 for the processor 620 to identify the first contact point 810 and the second contact point 820. In addition, two contact points may also be designed to have different diameters (as shown in FIG. 4, when the contact points 910 and 920 have different widths, a field pattern respectively having different widths P1 and P2 will be generated) for the processor 620 to identify the first contact point 810 and the second contact point 820 according to the width of the field. A height h1 of the first contact point 810 to the touch panel and the height h2 of the second contact point 820 to the touch panel are set to different heights so that the same voltage or frequency is output at the first contact point 810 and the second contact point 820 The touch-sensing unit 610 can still sense different intensities of the electrical signals to identify the two contact points.

In addition, when the processor 620 determines that the contact object is a control object, a prompt window may be displayed on the user interface to inform the user that the user can start executing the function corresponding to the control object.

Next, after the processor 620 determines that the touch object is the control object, the processor 620 enables the function corresponding to the control object according to the application currently executing. For example, when the display unit 640 is displaying a home screen of the operating system, the function corresponding to the control object may be the brightness control of the display screen. When the processor 620 is executing the multimedia playing program, the function corresponding to the control object may be a volume control or the adjustment of a timeline. When the processor 620 is executing a program related to a drawing program or a notebook, the function corresponding to the control object may be to change the brush color, adjust the stroke thickness, or switch the cursor function, for example. When the processor 620 is opening a web page or performing file browsing, such as browsing photos or PDFs, the function corresponding to the control object may be to zoom in on the browsing screen. When the processor 620 is running multimedia-editing software, the function corresponding to the control object may be to adjust the timeline or scroll a reel, for example. In addition, when the processor 620 determines that the control object has left the touch-sensing unit 610, the processor 620 disables the function corresponding to the control object.

In addition, after identifying the first contact point 810 and the second contact point 820, the processor 620 further determines a rotation angle of the control object according to the relative positions of the first contact point 810 and the second contact point 820 to perform the adjustment of the function corresponding to the control object. In this embodiment, the control object is a circulation type design, which means the knob can be infinitely rotated in a clockwise direction or a counterclockwise direction. For example, as shown in FIG. 4, after identifying the contact point A₀ as the center point and the contact point A₁ as the rotation point, the processor 620 determines a rotation radius “R” based on the coordinates of the contact point A₀ and the contact point A₁. Then, when the contact point A1 rotates in the counterclockwise direction, a rotation angle θ can be obtained according to a coordinate change of the contact point A₁ and a diameter “r” of the contact point A₁, so that the processor 620 can perform the adjustment of the function corresponding to the control object according to the rotation angle θ.

According to another embodiment of the present invention, a spring structure which can be disposed on the rotation shaft 830 may be further disposed between the knob 840 and the first contact point 810, (i.e., the center point) so that the user can press the knob 840 to change a distance between the first contact point 810 or the second contact point 820 and the touch panel. After the processor 620 determines that the touch object is the control object, when the touch-sensing unit 610 determines that the voltage intensity corresponding to the first contact point 810 or the second contact point 820 is changed, i.e., the user presses the knob 840, the touch-sensing unit 610 generates and outputs a click signal to the processor 620 so as to enable the processor 620 to output another command corresponding to the application, such as a confirmation command. In addition, the processor 620 may also generate different instructions according to a change of the voltage intensity. For example, when the variation is smaller than a predetermined value, which indicates that the user taps the knob 840, and the processor 620 outputs the confirmation instruction. On the other hand, when the variation is greater than the predetermined value, which indicates that the user presses the knob 840 vigorously, and the processor 620 outputs an instruction to disable the application program.

According to another embodiment of the present invention, when the user presses the knob 840 so that the signal strength of the first contact point 810 or the second contact point 820 is changed, the processor 620 may further output different instructions according to the length of the pressing time. For example, when the user presses the knob 840 for less than 3 seconds, the processor 620 outputs the click signal corresponding to the confirmation instruction. When the user presses the knob 840 for more than or equal to 3 seconds, the processor 620 outputs a long-press signal corresponding to a call setting-window instruction.

According to another embodiment of the present invention, in addition to determining whether the touch object is the control object according to the touch-sensing information of the touch object, the processor 620 may further enable different functions according to the coordinates of the touch object. For example, after the processor 620 determines that the touch object is the control object, the user can use different functions by placing the touch object in different sub-areas on the touch screen.

It should be noted that the processor 620 can match the conditions described above, i.e., the change of voltage intensity, the length of the pressing time, and the coordinates, to each other according to the user's requirement to output different instructions or to enable different functions. In addition, the instruction settings described above are only examples, and the user may adjust the instruction corresponding to each signal according to the requirement.

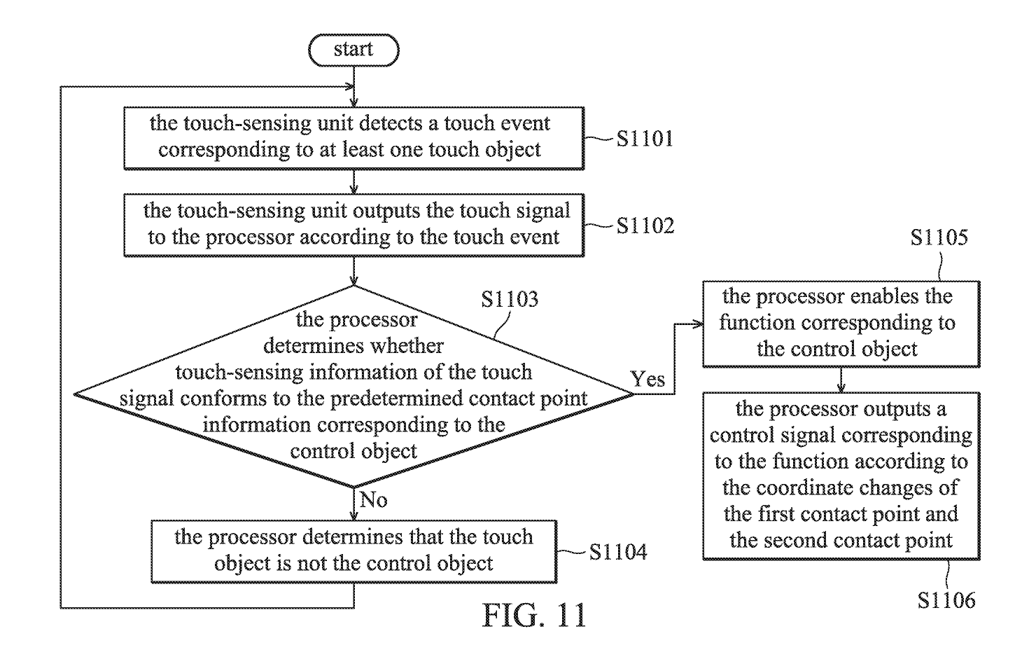

FIG. 11 is a flow chart of a method for sensing the touch object in accordance with an embodiment of the invention. In step S1101, the touch-sensing unit 610 detects a touch event corresponding to at least one touch object. In step S1102, the touch-sensing unit 610 outputs the touch signal S_{T} to the processor 620 according to the touch event. In step S1103, the processor 620 receives the touch signal S_{T} and determines whether touch-sensing information of the touch signal S_{T} conforms to the predetermined contact point information corresponding to the control object. The predetermined contact point information system includes the first electrical signal corresponding to the first contact point and the second electrical signal corresponding to the second contact point. If the touch-sensing information does not conform to the predetermined contact point information, the method proceeds to step S1104, the processor 620 determines that the touch object is not the control object and selectively generates a touch signal corresponding to the touch position, and the method returns to step S1101, the touch-sensing unit 610 detects the touch event of the touch object again. On the contrary, if the touch-sensing information conforms to the predetermined contact point information, the method proceeds to step S1105, the processor 620 enables the function corresponding to the control object. In step S1106, the processor 620 further outputs a control signal corresponding to the function according to the coordinate changes of the first contact point and the second contact point.

As described above, according to the electronic device, the method for controlling an user interface, and the method for sensing touch objects provided in the embodiments of the present invention, by storing the predetermined contact point information in the storage device in advance, when the touch-sensing unit of the electronic device detects the touch object, the processor of the electronic device can determine whether the touch object is the control object according to the electrical signal output by the touch object and the predetermined contact point information so as to enable the specific function corresponding to the control object. By using the method as described above, the control object can provide additional control without additional connecting wires or wireless communication modules, thereby the cost of the input device can be reduced and a better user experience can also be provided.

It will be apparent to those skilled in the art that various modifications and variations can be made to the structure disclosed without departing from the scope or spirit of the invention. In view of the foregoing, it is intended that the present invention covers modifications and variations of this invention, provided they fall within the scope of the following claims and their equivalents.

What is claimed is:

1. An electronic device comprising:
a storage device, storing predetermined contact point information corresponding to a control object;
a touch sensing unit, detecting a touch event corresponding to at least one touch object, and outputting a touch signal; and
a processor, receiving the touch signal and determining whether contact point information of the touch signal conforms to the predetermined contact point information corresponding to the control object;
wherein when the processor determines that the contact point information of the touch signal conforms to the predetermined contact point information, the processor enables a function corresponding to the control object.

2. The electronic device as claimed in claim 1, wherein the contact point information comprises relative position of at least two contact points, number of contact points and/or induction corresponding to each contact point.

3. The electronic device as claimed in claim 1, wherein when the processor determines that the contact point information of the touch signal conforms to the predetermined contact point information, the processor further outputs a control signal corresponding to the function according to a coordinate change of at least one contact point and/or a rotation angle corresponding to the coordinate change of the touch object.

4. The electronic device according to claim 1, wherein the control object is an electroless element, and the contact point of the control object is composed of a conductive element.

5. An electronic device as claimed in claim 1, wherein the control object is a knob element.

6. A method for controlling a user interface, adapted to an electronic device, comprising:
detecting, via a touch sensing unit, a touch event corresponding to at least one touch object;
outputting, via the touch sensing unit, a touch signal according to the touch event;
receiving, via a processor, the touch signal from the touch sensing unit; and
determining, via the processor, whether contact point information of the touch signal conforms to predetermined contact point information corresponding to a control object, wherein the predetermined contact point information is stored in a storage device;
wherein when the contact point information of the touch signal conforms to the predetermined contact point information, the processor enables a function that corresponds to the control object.

7. The method as claimed in claim 6, wherein the step of determining whether or not the contact point information of the touch signal conforms to the predetermined contact point information corresponding to the control object further comprises:
determining whether the touch object is the control object according to the relative position of at least two contact points, number of contact points and/or induction corresponding to each contact point.

8. The method as claimed in claim 6, wherein when the contact point information of the touch signal conforms to the predetermined contact point information, further outputting a control signal corresponding to the function according to a coordinate change of at least one contact point and/or a rotation angle corresponding to the coordinate change of the touch object through the processor.

9. The method as claimed in claim 6, wherein the control object is an electroless element, and the contact point of the control object is composed of a conductive element.

10. The method as claimed in claim 6, wherein the control object is a knob element.

11. An electronic device, comprising:
a storage device, storing predetermined contact point information corresponding to a control object, wherein the predetermined contact point information comprises a first electrical signal corresponding to a first contact point and a second electrical signal corresponding to a second contact point;
a touch-sensing unit, detecting a touch event corresponding to at least one touch object, and outputting a touch signal; and
a processor, receiving the touch signal, and determining whether the touch-sensing information corresponding to the touch signal conforms to the predetermined contact point information corresponding to the control object;
wherein when the processor determines that the touch-sensing information of the touch signal conforms to the predetermined contact point information, the processor enables a function corresponding to the control object.

12. The electronic device as claimed in claim 11, wherein the control object is a knob element that has a first contact point, a second contact point, a power supply unit, a microprocessor, and a boosted circuit.

13. The electronic device as claimed in claim 12, wherein the microprocessor further outputs the electrical signals via the first contact point and the second contact point through the boosted circuit, wherein the electrical signals are voltage strength, frequencies and/or field patterns.

14. The electronic device as claimed in claim 12, wherein the first contact point and the second contact point have different heights or different shapes.

15. The electronic device as claimed in claim 12, wherein the processor identifies the first contact point and the second contact point according to voltage, frequency, height, or shape corresponding to the first contact point and the second contact point.

16. A method for sensing a touch object, adapted to an electronic device, comprising:
detecting, using a touch-sensing unit, a touch event corresponding to at least one touch object;
outputting, using the touch-sensing unit, a touch signal according to the touch event;
receiving, using a processor, the touch signal from the touch-sensing unit; and
determining, using the processor, whether touch-sensing information corresponding to the touch signal conforms to predetermined contact point information corresponding to a control object;
wherein the predetermined contact point information further comprises a first electrical signal corresponding to a first contact point and a second electrical signal corresponding to a second contact point, and the predetermined contact point information is stored in a storage device; and
wherein the processor enables the function that corresponds to the control object when the touch-sensing information of the touch signal conforms to the predetermined contact point information.

17. The method as claimed in claim 16, wherein the control object is a knob element that has a first contact point, a second contact point, a power supply unit, a microprocessor, and a boosted circuit.

18. The method as claimed in claim 17, further comprising:
outputting, using the microprocessor, electrical signals via the first contact point and the second contact point respectively through the boosted circuit, wherein the electrical signals are voltage strength, frequencies and/or field patterns.

19. The method as claimed in claim 17, wherein the first contact point and the second contact point have different heights or different shapes.

20. The method as claimed in claim 17, further comprising:
identifying, using the processor, the first contact point and the second contact point according to the voltage, frequency, height, or shape corresponding to the first contact point and the second contact point.
